(19) United States
(12) Patent Application Publication
(10) Pub. No.: US 2025/0221121 A1
(43) Pub. Date: Jul. 3, 2025

(54) Display Device and Display Panel

(71) Applicant: LG Display Co., Ltd., Seoul (KR)

(72) Inventors: JaeHyoung Park, Paju-si (KR); HyoKyeong Son, Paju-si (KR); Yeonjae Jeong, Paju-si (KR)

(21) Appl. No.: 18/914,543

(22) Filed: Oct. 14, 2024

(30) Foreign Application Priority Data
Dec. 28, 2023 (KR) 10-2023-0193880

(51) Int. Cl. H01L 33/64; H01L 25/075; H01L 33/62

(52) U.S. Cl. CPC H10H 20/8586; H01L 25/0753; H10H 20/857; H10H 20/8581

(57) ABSTRACT

A display device and a display panel. The display device includes a driving circuit configured to drive the display panel. The display panel includes a plurality of light-emitting elements. The display panel includes a first substrate with the driving circuit being provided on a first surface thereof, a second substrate with the light-emitting elements being disposed on a top portion thereof, and a heat dissipation sheet disposed between the first substrate and the second substrate. The heat dissipation sheet includes a path pattern allowing liquid metal to flow therethrough.

### CROSS REFERENCE TO RELATED APPLICATION

This application claims priority from Republic of Korea Patent Application No. 10-2023-0193880, filed on Dec. 28, 2023, which is hereby incorporated by in its entirety.

### BACKGROUND

### Field

Embodiments relate to a display device and, more particularly, to a display device and a display panel including a heat dissipation sheet in which a path pattern allowing liquid metal to flow therethrough may be disposed between substrates to improve heat dissipation performance.

### Description of Related Art

With the development of the information society, demand for various types of display devices for displaying images is increasing. In this regard, a range of display devices, such as liquid crystal display (LCD) devices and organic light-emitting display devices, have recently come into widespread use.

Among such display devices, a LCD device needs a backlight unit disposed to emit light to the bottom (or rear side) thereof, since the LCD device is not self-luminous. Due to the additional backlight unit, the thickness of the LCD device increases. There are limitations in implementing the display device in various designs such as a flexible or circular design. In addition, the luminance and response rate of the LCD device may be reduced.

A display device having self-luminous elements may be designed to be thinner than a display device having a light source disposed therein, and may advantageously be implemented as a flexible and foldable display device.

Display devices having self-luminous elements include organic light-emitting display devices including an organic material as a light-emitting layer and micro-LED display devices using micro light-emitting diodes (LEDs) as light-emitting elements. Self-luminous devices such as organic light-emitting display devices or micro-LED display devices do not require a separate light source and may therefore be implemented as thinner or more versatile display devices.

Accordingly, in recent years, research and development of display devices using microscopic-sized micro-LEDs as light-emitting elements has been undertaken, and such display devices are attracting attention as next-generation display devices due to high definition and high reliability thereof.

In such a micro-LED display device, micro LEDs are transferred to a first substrate, a circuit including transistors is formed on a second substrate, and the first substrate and the second substrate are bonded to each other. In the process of joining the edges of the first substrate and the second substrate using a sealant, a gap equal to the sealant must be maintained between the first substrate and the second substrate so that the image quality may be displayed reliably.

Therefore, heat generated during the driving process of the display device may be trapped in the internal space between the first substrate and the second substrate, thereby causing the display panel or the driving circuit to deteriorate and affecting the image quality or lifespan of the display device.

In particular, the area in which the driving circuit is located may generate a large amount of heat, thereby leading to significant deterioration of the display panel.

### SUMMARY

In this regard, the inventors of the present disclosure have invented a display device and a display panel having improved heat dissipation performance.

Embodiments may provide a display device and a display panel including a heat dissipation sheet having a path pattern allowing liquid metal to flow therethrough may be disposed between substrates to improve heat dissipation performance.

Embodiments may also provide a display device and a display panel in which the density of the path pattern allowing liquid metal to flow therethrough in areas in which high temperature heat is generated may be increased so as to effectively improve heat dissipation performance.

Embodiments may also provide a display device and a display panel in which the mobility of liquid metal flowing along the path pattern may be controlled using a flow voltage so as to control heat dissipation performance based on the position.

Embodiments may provide a display device including: a display panel including a plurality of light-emitting elements; a driving circuit configured to drive the display panel. The display panel may include: a first substrate with the driving circuit being provided on a first surface thereof; a second substrate with the light-emitting elements being disposed on a top portion thereof; and a heat dissipation sheet disposed between the first substrate and the second substrate, and including a path pattern allowing liquid metal to flow therethrough.

Embodiments may provide a display panel including: a first substrate with a driving circuit being provided on a first surface thereof; a second substrate with light-emitting elements being disposed on a top portion thereof; and a heat dissipation sheet disposed between the first substrate and the second substrate, and including a path pattern allowing liquid metal to flow therethrough.

Embodiments may provide a display device including: a plurality of display panels disposed adjacent to each other; and a plurality of driving circuits configured to drive the display panels, respectively. Each of the display panels may include: a first substrate with the driving circuit being provided on a first surface thereof; a second substrate with light-emitting elements being disposed on a top portion thereof; and a heat dissipation sheet disposed between the first substrate and the second substrate, and including a path pattern allowing liquid metal to flow therethrough.

According to embodiments, the display device and the display panel may have improved heat dissipation performance.

According to embodiments, the heat dissipation sheet having the path pattern allowing liquid metal to flow therethrough may be disposed between substrates to improve heat dissipation performance and realize the effects of low power consumption and greenhouse gas reduction.

According to embodiments, the density of the path pattern allowing liquid metal to flow therethrough may be increased in areas in which high temperature heat is generated so as to effectively improve heat dissipation performance.

According to embodiments, the mobility of liquid metal flowing along the path pattern may be controlled using a flow voltage so as to control heat dissipation performance according to the position.

### BRIEF DESCRIPTION OF DRAWINGS

The above and other objectives, features, and advantages of the present disclosure will be more clearly understood from the following detailed description, taken in conjunction with the accompanying drawings, in which:

FIG. 1 illustrates a schematic configuration of a display device according to embodiments of the present disclosure;

FIG. 2 is a perspective view illustrating the display device according to embodiments of the present disclosure;

FIG. 3 is a perspective view schematically illustrating a display panel according to embodiments of the present disclosure;

FIG. 4 illustrates an example of a single subpixel circuit in the display device according to embodiments of the present disclosure;

FIG. 5 is a cross-sectional view specifically illustrating the structure of the display device according to embodiments of the present disclosure;

FIG. 6 is a plan view conceptually illustrating the structure of the heat dissipation sheet disposed between the first substrate and the second substrate in the display device according to embodiments of the present disclosure;

FIG. 7 is a signal waveform diagram illustrating an example operation of the flow voltage pad in the display device according to embodiments of the present disclosure;

FIGS. 8 to 11 are perspective views illustrating an example process of fabricating a display panel according to embodiments of the present disclosure;

FIG. 12 is an enlarged perspective view of part B of FIG. 11 according to embodiments of the present disclosure;

FIG. 13 is a cross-sectional view taken along line A-A′ of FIG. 12 according to embodiments of the present disclosure;

FIG. 14 is a signal waveform diagram illustrating another example operation of the flow voltage pad in the display device according to embodiments of the present disclosure;

FIG. 15 illustrates an example of a signal line connecting configuration on the display backside in the display device according to embodiments of the present disclosure;

FIG. 16 schematically illustrates a tiled display device in which a plurality of display panels are disposed adjacent to each other according to embodiments of the present disclosure; and

FIG. 17 illustrates a case in which the display panel of the display device has different path patterns in a high temperature area and a low temperature area according to embodiments of the present disclosure.

### DETAILED DESCRIPTION

Hereinafter, some embodiments of the present disclosure will be described in detail with reference to exemplary drawings. In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the accompanying drawings.

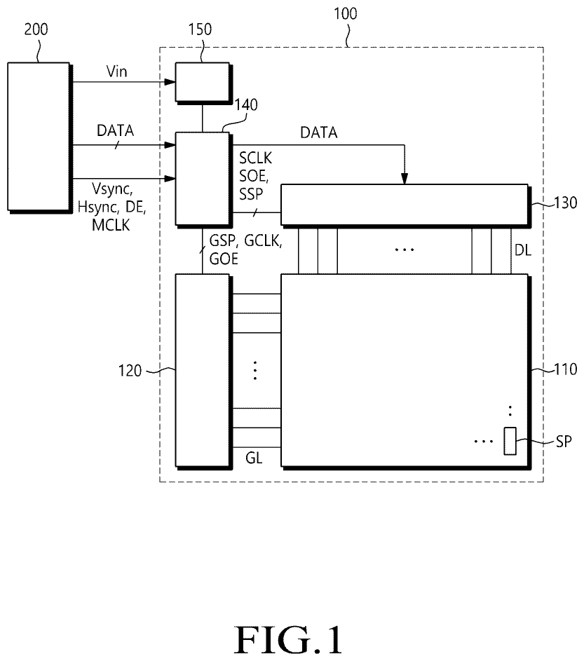

FIG. 1 illustrates a schematic configuration of a display device according to embodiments of the present disclosure.

Referring to FIG. 1, a display device 100 according to embodiments may include: a display panel 110 having a plurality of gate lines GL and a plurality of data lines DL connected thereto and a plurality of subpixels SP arranged in a matrix; a gate driving circuit 120 configured to drive the gate lines GL; a data driving circuit 130 configured to supply a data voltage through the data lines DL; a timing controller 140 controlling the gate driving circuit 120 and the data driving circuit 130; and a power management circuit 150.

The display panel 110 displays an image in a display area based on a gate signal transmitted from the gate driving circuit 120 through the gate lines GL and a data voltage transmitted from the data driving circuit 130 through the data lines DL.

The gate signals delivered by the gate driving circuit 120 may include a scanning signal used as a control signal for driving the subpixels, an emission signal used as a control signal for an emission operation of light-emitting elements, or a sensing signal used as a control signal for sensing a voltage of a specific node.

The display panel 110 may include a plurality of pixels arranged in a matrix, each pixel including subpixels SP for different colors, such as a white subpixel, a red subpixel, a green subpixel, and a blue subpixel. The respective subpixels SP may be defined by the data lines DL and the gate lines GL.

A single subpixel SP may include a thin film transistor TFT provided in an area in which a single data line DL and a single gate line GL intersect, a light-emitting element, such as a micro-LED, emitting light using a data voltage, and a storage capacitor electrically connected to the light-emitting element to maintain a voltage.

For example, in a case in which the display device 100 having a definition of 2,160×3,840 includes three subpixels SP, i.e., red (R), green (G), and blue (B) subpixels, there may be 2,160 gate lines GL and a total of 11,520 data lines (DL) provided by 3,840 data lines DL respectively connected to the three (RGB) subpixels SP: 3,840×3=11,520, and each of the subpixels SP may be disposed at the intersection of a gate line GL and a data line DL.

The gate driving circuit 120 is controlled by the timing controller 140, and controls the driving timing for the subpixels SP by sequentially outputting gate signals to the gate lines GL disposed on the display panel 110.

In a case in which the display device 100 having a resolution of 2,160×3,840 sequentially outputs a gate signal to 2,160 gate lines (GL) from the first gate line to the 2,160th gate line, this may be referred to as 2,160 phase driving. In another example, in a case in which a gate signal is output sequentially to first four gate lines from the first gate line to the fourth gate line and then the gate signal is output sequentially to the next four gate lines from the fifth gate line to the eighth gate line, i.e., the gate signal is output sequentially to gate line groups each including four gate lines GL, this may be referred to as four-phase driving. In other words, in a case in which the gate signal is output sequentially to gate line groups each including N number of gate lines GL is referred to as N-phase operation.

In this case, the gate driving circuit 120 may include one or more gate driver integrated circuits (GDICs), which may be located on only a first side or on opposite sides of the display panel 110, depending on the driving system. In another example, the gate driving circuit 120 may be embedded in a bezel of the display panel 110 to have a gate-in-panel (GIP) structure.

The data driving circuit 130 receives image data DATA from the timing controller 140, and converts the received image data DATA into an analog data voltage. Thereafter, the data voltage is output to the data lines DL through the gate lines GL, respectively, according to the application timing of the gate signal, so that each of the subpixels SP connected to the data lines DL displays an emission signal having a brightness corresponding to the data voltage.

Similarly, the data driving circuit 130 may include one or more source driver integrated circuits (SDICs), which may be connected to bonding pads of the display panel 110 using a tape-automated-bonding (TAB) method or a chip-on-glass (COG) method, or may be disposed directly on the display panel 110.

In some cases, each of the source driver integrated circuits may be integrated on the display panel 110. In addition, each of the source driver integrated circuits may be implemented using a chip-on-film (COF) method. In this case, each of the source driver integrated circuits may be mounted on a circuit film and electrically connected to a data line DL of the display panel 110 through the circuit film.

The timing controller 140 supplies various control signals to the gate driving circuit 120 and the data driving circuit 130, and controls the operation of the gate driving circuit 120 and the data driving circuit 130. In other words, the timing controller 140 controls the gate driving circuit 120 to output the gate signal according to the timing realized for each frame, and, on the other hand, delivers the externally received image data DATA to the data driving circuit 130.

Here, the timing controller 140 receives several timing signals, including a vertical synchronization signal Vsync, a horizontal synchronization signal Hsync, a data enable signal DE, and a main clock MCLK, together with the image data DATA from an external host system 200.

The host system 200 may be any one of a television system, a set-top box, a navigation system, a personal computer (PC), a home theater system, a mobile device, or a wearable device.

Accordingly, the timing controller 140 generates control signals using various timing signals received from the host system 200 and delivers the control signals to the gate driving circuit 120 and the data driving circuit 130.

For example, the timing controller 140 outputs various gate control signals, including a gate start pulse GSP, a gate clock GCLK, and a gate output enable signal GOE, to control the gate driving circuit 120. The gate start pulse GSP controls the timing at which the gate driver integrated circuits of the gate driving circuit 120 start operating. In addition, the gate clock GCLK is a clock signal input to the gate driver integrated circuits in common to control the shift timing of the gate signal. In addition, the gate output enable signal GOE specifies timing information of the gate driver integrated circuits.

The timing controller 140 also outputs various data control signals, including a source start pulse SSP, a source clock SCLK, and a source output enable signal SOE, to control the data driving circuit 130. Here, the source start pulse SSP controls the timing at which the source driver integrated circuits of the data driving circuit 130 start data sampling. The source clock SCLK is a clock signal to control the timing of the data sampling by the source driver integrated circuits. The source output enable signal SOE controls the output timing of the data driving circuit 130.

Such a display device 100 may include a power management circuit 150 that supplies various voltages or currents to, or controls various voltages or currents to be supplied to, the display panel 110, the gate driving circuit 120, the data driving circuit 130, and the like.

The power management circuit 150 regulates a direct current input voltage Vin supplied from the host system 200 to generate power required to drive the display panel 100, the gate driving circuit 120, and the data driving circuit 130.

On the other hand, the subpixels SP may be located at the intersections of the gate lines GL and the data lines DL, and a light-emitting element may be disposed in each of the subpixels SP. For example, a micro-LED display device may include light-emitting elements, such as micro LEDs, in the subpixels SP, respectively, and may display an image by controlling a current flowing to the light-emitting elements using a data voltage.

Such display devices 100 may be various types of devices, such as micro-LED displays, liquid crystal displays, organic light-emitting displays, plasma display panels, and the like.

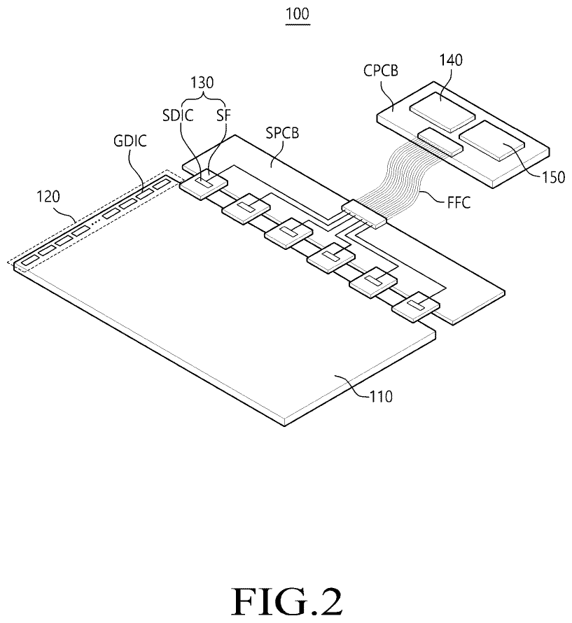

FIG. 2 is a perspective view illustrating the display device according to embodiments of the present disclosure.

Referring to FIG. 2, the display device 100 according to embodiments is illustrated as configured such that one or more source driver integrated circuits SDIC included in a data driving circuit 130 and one or more gate driver integrated circuits GDIC included in a gate driving circuit 120 are implemented using a gate-in-panel (GIP) structure among various structures (e.g., TAB, COG, and COF structures).

Each of the gate driver integrated circuits GDIC included in the gate driving circuit 120 may be mounted on a gate film GF, and a first side of the gate film GF may be electrically connected to the display panel 110. In addition, wiring (or signal lines) for electrically connecting the gate driver integrated circuits GDIC and the display panel 110 may be disposed on the top portion of the gate film GF.

Similarly, the source driver integrated circuits SDIC included in the data driving circuit 130 may be mounted on source films SF, and a first side of each of the source films SF may be electrically connected to the display panel 110. In addition, wiring for electrically connecting the source driver integrated circuits SDICs and the display panel 110 may be disposed on the top portions of the source films SF.

Such a display device 100 may include at least one source printed circuit board SPCB and a control printed circuit board CPCB on which control components and various electrical devices are mounted for circuit connection between the source driver integrated circuits SDIC and other devices.

Here, the source printed circuit board SPCB may be connected to second sides of the source films SF on which the source driver integrated circuits SDIC are mounted. That is, the source films SF on which the source driver integrated circuits SDIC are mounted may be electrically connected at the first sides to the display panel 110 and electrically connected at the second sides to the source printed circuit board SPCB.

The control printed circuit board CPCB may have the timing controller 140 and the power management circuit 150 mounted thereon. The timing controller 140 may control the operation of the data driving circuit 130 and the gate driving circuit 120. The power management circuit 150 may supply a driving voltage or current to, or control the voltage or current supplied to, the display panel 110, the data driving circuit 130, the gate driving circuit 120, and the like.

The source printed circuit board SPCB and the control printed circuit board CPCB may be circuit-connected by at least one connecting member. The connecting member may include, for example, a flexible printed circuit (FPC), flexible flat cable FFC, or the like. In this case, the connecting member connecting the source printed circuit board SPCB and the control printed circuit board CPCB may vary depending on the size and type of the display device 100. In addition, the source printed circuit board SPCB and the control printed circuit board CPCB may be integrated and implemented on a single printed circuit board.

In the display device 100 having the above-described configuration, the power management circuit 150 delivers the driving voltage required for display driving or characteristic values sensing to the source printed circuit board SPCB through the flexible printed circuit or the flexible flat cable FFC. The driving voltage delivered to the source printed circuit board SPCB is supplied to emit light or sense specific subpixels SP in the display panel 110 through the source driver integrated circuits SDIC.

In this case, each of the subpixels SP arranged in the display panel 110 of the display device 100 may include a micro LED as a light-emitting element and a circuit element such as a driving transistor to drive the micro LED.

The type and number of circuit elements of each subpixel (SP) may vary depending on the functionality provided by the subpixel SP, the design of the subpixel SP, and the like.

In the following, a display device using micro-LEDs as light-emitting elements are described as an example.

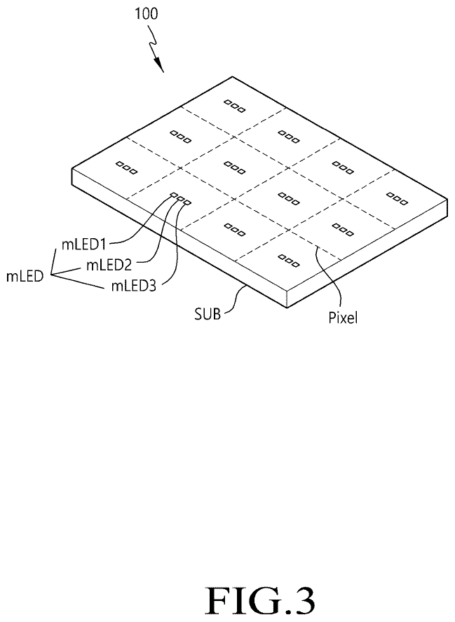

FIG. 3 is a perspective view schematically illustrating a display panel according to embodiments of the present disclosure.

Referring now to FIG. 3, a display panel 110 according to embodiments may include a substrate SUB and a plurality of micro-LEDs mLED mounted on a substrate SUB.

The substrate SUB may include a transparent material, such as glass, on which a plurality of pixels Pixel are formed. In each of the pixels Pixel, a plurality of micro-LEDs mLED1, mLED2, and mLED3, a plurality of transistors for driving the micro-LEDs, and signal lines may be formed.

In the display panel 110, in a state where the driving transistors for driving the micro-LEDs mLED are turned on, the micro-LEDs mLED are turned on by the data voltage applied through the data lines DL to display an image.

In this regard, three micro-LEDs mLED1, mLED2, and mLED3 emitting monochromatic colors of light including red light, green light, and blue light, respectively, may be mounted on each of the pixels Pixel of the substrate SUB, and the data voltage causes each of the micro-LEDs mLED1, mLED2, and mLED3 to emit light of the corresponding color.

Here, the area in which the red micro-LED mLED1, the green micro-LED mLED2, or the blue-colored micro-LED mLED3 is individually located may be a subpixel SP. Thus, a single pixel may include a red subpixel, a green subpixel, and a blue subpixel.

The micro-LEDs mLED1, mLED2, and mLED3 located on the display panel 110 may be fabricated by a process separate from the transistor process on the substrate SUB.

For example, in the micro-LED display device 100, the transistors and various signal lines disposed on the substrate SUB are formed by photolithography, but the micro-LEDs mLED1, mLED2, and mLED3 are fabricated by a separate process, and may be fabricated by transferring the separately fabricated micro LEDs mLED1, mLED2, and mLED3 onto the substrate SUB.

The micro-LEDs mLED are light-emitting diodes having a size of 10 μm to 100 μm, and may be fabricated by growing a thin film of an inorganic material, such as Al, Ga, N, P, As, or In, on a sapphire substrate or a silicon (Si) substrate, and then cutting and dividing the sapphire substrate or silicon substrate. Since the micro-LEDs mLED are fabricated in a microscopic size in this manner, the micro-LEDs mLED may be transferred to a flexible substrate formed of, for example, plastic, thereby enabling the fabrication of flexible display devices. In addition, since the micro-LEDs mLED are formed by thin film growth of an inorganic material, unlike organic light-emitting layers, the fabrication process thereof may be simplified and the yield thereof may be improved.

In addition, since the individually separated micro-LEDs mLED are transferred onto a large substrate SUB, large display devices may be easily fabricated. Accordingly, the micro-LEDs mLED formed of an inorganic material have the advantages of high brightness, long lifetime, and low fabrication cost compared to light-emitting elements using an organic material.

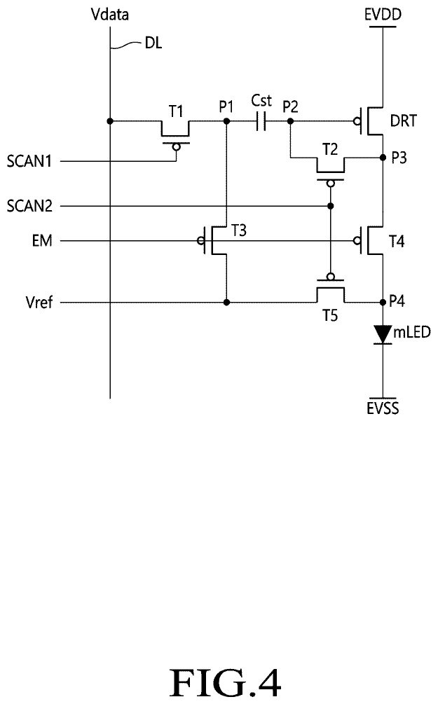

FIG. 4 illustrates an example of a single subpixel circuit in the display device according to embodiments of the present disclosure.

Referring to FIG. 4, the subpixel circuit of the display device 100 according to embodiments may include a micro-LED mLED, a driving transistor DRT, a plurality of switching transistors T1 to T5, and a storage capacitor Cst.

The driving transistor DRT and the plurality of switching transistors T1 to T5 included in the subpixel circuit may be implemented as PMOS low-temperature polycrystalline silicon (LTPS) transistors to achieve desired response characteristics.

In another example, at least one of the switching transistors T1 to T5 may be implemented as an NMOS or PMOS oxide transistor having good turn-off leakage current characteristics, and the remaining switching transistors may be implemented as PMOS LTPS transistors having good response characteristics.

The micro-LED mLED generates light using a driving current regulated by a gate-to-source voltage Vgs of the driving transistor DRT. The anode of the micro-LED mLED is connected to a fourth node P4, and the cathode of the micro-LED mLED is connected to a low-potential pixel voltage EVSS.

The driving transistor DRT controls the current flowing through the micro-LED mLED according to the gate-source voltage Vgs. The gate electrode of the driving transistor DRT is connected to a second node P2, the drain electrode (or source electrode) is connected to a driving voltage line through which a high-potential pixel voltage EVDD is supplied, and the source electrode (or drain electrode) is connected to a third node P3.

The subpixel circuit may include the first to fifth switching transistors T1 to T5 and the storage capacitor Cst, by which the gate-source voltage Vgs may be sampled to compensate for the threshold voltage or the mobility of the driving transistor DRT.

The first switching transistor T1 is connected to a data line DL and a first node P1, and is switched according to a first scanning signal (SCAN1). In the first switching transistor T1, the gate electrode is connected to a first gate line to which the first scanning signal SCAN1 is applied, the drain electrode (or source electrode) is connected to the data line DL, and the source electrode (or drain electrode) is connected to the first node P1.

The second switching transistor T2 is connected to the second node P2 and the third node P3, and is switched according to a second scanning signal SCAN2. In the second switching transistor T2, the gate electrode is connected to a second gate line to which the second scanning signal SCAN2 is applied, the drain electrode (or source electrode) is connected to the third node P3, and the source electrode (or drain electrode) is connected to the second node P2.

In the second switching transistor T2, one electrode is connected to the gate electrode of the driving transistor DRT, and thus it is desirable for the second switching transistor T2 to have a good off-current characteristic. Therefore, the second switching transistor T2 may be designed to have a dual gate structure to reduce turn-off leakage current.

In the dual gate structure, the first gate electrode and the second gate electrode are connected to each other so as to have the same potential, and the channel length is increased compared to that of a single gate structure. The longer channel length may increase the resistance and reduce the turn-off leakage current, thereby achieving the stability of operation. However, the second switching transistor T2 may also be implemented using a single gate structure, in which case the second switching transistor T2 may be implemented as an oxide transistor.

The third switching transistor T3 is connected to the first node P1 and a reference voltage line to which a reference voltage Vref is applied, and is switched according to an emission signal EM. In the third switching transistor T3, the gate electrode is connected to a third gate line to which the emission signal EM is applied, the drain electrode (or source electrode) is connected to the first node P1, and the source electrode (or drain electrode) is connected to the reference voltage line.

The fourth switching transistor T4 is connected to the third node P3 and the fourth node P4, i.e., the anode of a light-emitting element ED, and is switched according to the emission signal EM. In the fourth switching transistor T4, the gate electrode is connected to the third gate line to which the emission signal EM is applied, the drain electrode (or source electrode) is connected to the third node P3, and the source electrode (or drain electrode) is connected to the fourth node P4. Since the fourth switching transistor T4 controls the driving current flowing to the micro-LED mLED, the fourth switching transistor T4 may be referred to as a light emission control transistor.

The fifth switching transistor T5 is connected to the fourth node P4 and the reference voltage line, and is switched according to the second scanning signal SCAN2. In the fifth switching transistor T5, the gate electrode is connected to the second gate line to which the second scanning signal SCAN2 is applied, the drain electrode (or source electrode) is connected to the fourth node P4, and the source electrode (or drain electrode) is connected to the reference voltage line.

The storage capacitor Cst is connected to the first node P1 and the second node P2.

The structure of the subpixel circuit described above as an example is a 6T1C structure including six (6) transistors and one (1) capacitor, which is provided for illustrative purposes only, and may further include one or more transistors or, in some cases, one or more capacitors. In another example, the respective subpixels SP may have the same structure, and some of the subpixels SP may have different structures.

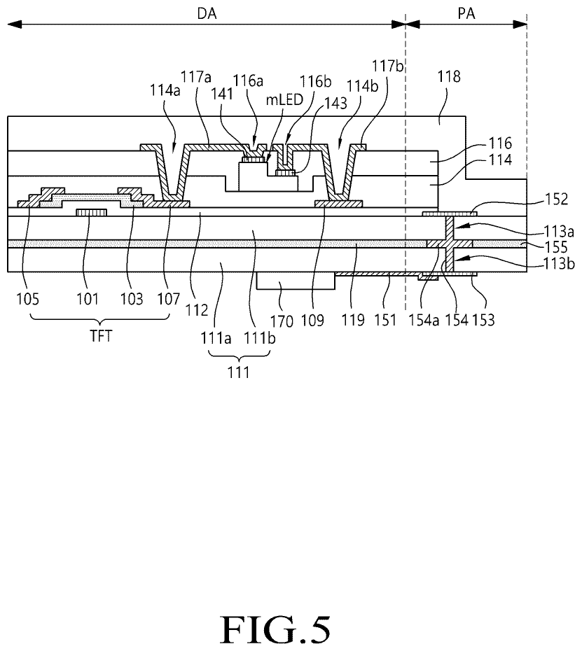

FIG. 5 is a cross-sectional view specifically illustrating the structure of the display device according to embodiments of the present disclosure.

Referring to FIG. 5, the display device 100 according to embodiments may include a thin-film transistor TFT disposed in a display area DA of a substrate 111 and pads 152 and 153 disposed in a pad area PA of the substrate 111.

The substrate 111 includes a first substrate 111a and a second substrate 111b, which may be bonded to each other by a sealant 155 provided in the pad area PA. In this case, each of the first substrate 111a and the second substrate 111b may be formed of, but is not limited to, a transparent material such as glass, and may also be formed of other transparent materials. For example, the first substrate 111a and the second substrate 111b may include a flexible transparent material. In addition, the first substrate 111a and the second substrate 111b may be formed of the same material or may be formed of different materials.

In addition, a heat dissipation sheet 119 having a path pattern allowing liquid metal to flow therethrough may be disposed in the display area DA between the first substrate 111a and the second substrate 111b. The path pattern formed in the heat dissipation sheet 119 may be injected with liquid metal capable of flowing using an electric flow voltage. The path pattern formed in the heat dissipation sheet 119 may include a plurality of separated paths, and the shape of the path patterns may vary depending on the position of the display panel 110.

The thin-film transistor TFT may include a gate electrode 101 formed over a second substrate 111b, a gate insulating layer 112 covering the gate electrode 101 over the entire area of the second substrate 111b, a semiconductor layer 103 formed on the gate insulating layer 112, a source electrode 105 formed over the semiconductor layer 103, and a drain electrode 107.

The gate electrode 101 may be formed of a metal, such as chromium (Cr), molybdenum (Mo), tantalum (Ta), copper (Cu), titanium (Ti), aluminum (Al), or an alloy thereof.

The gate insulating layer 112 may include a single layer formed of an inorganic insulating material, such as silicon oxide (SiOx) or silicon nitride (SiNx), or a laminated structure of multiple layers formed of silicon oxide (SiOx) and silicon nitride (SiNx).

The semiconductor layer 103 may include an amorphous semiconductor, such as amorphous silicon, or may include an oxide semiconductor, such as indium-gallium-zinc oxide (IGZO), titanium oxide (TiO₂), zinc oxide (ZnO), tungsten oxide (WO₃), or tin oxide (SnO₂). When the semiconductor layer 103 is formed of an oxide semiconductor, the size of the thin-film transistor TFT may be reduced, driving power may be reduced, and electric mobility may be improved.

Each of the source electrode 105 and the drain electrode 107 may be formed of a metal, such as chromium (Cr), molybdenum (Mo), tantalum (Ta), copper (Cu), titanium (Ti), aluminum (Al), or an alloy thereof.

The drain electrode 107 may act as a first electrode to apply a signal to a micro-LED mLED.

The first pad 152 disposed in the pad area PA may be formed of a metal, such as chromium (Cr), molybdenum (Mo), tantalum (Ta), copper (Cu), titanium (Ti), aluminum (Al), or an alloy thereof. The first pad 152 may be formed by a different process than the gate electrode 101 of the thin-film transistor TFT, but for process simplicity, may be formed by the same process as the gate electrode 101. In this case, the first pad 152 may be formed over the gate insulating layer 112.

The first pad 152 may be formed by a different process than the source electrode 105 and the drain electrode 107 of the thin-film transistor TFT, but for process simplicity, may be formed by the same process as the source electrode 105 and the drain electrode 107.

A second electrode 109 is formed over the gate insulating layer 112 of the display area DA. The second electrode 109 may be formed of a metal, such as chromium (Cr), molybdenum (Mo), tantalum (Ta), copper (Cu), titanium (Ti), aluminum (Al), or an alloy thereof, and may be formed by the same process as the drain electrode 107 of the thin-film transistor TFT.

A first insulating layer 114 is formed over the second substrate 111b on which the thin-film transistor TFT is formed, and the micro-LED mLED is disposed over the first insulating layer 114 in the display area DA. It is shown here that a portion of the first insulating layer 114 is removed and the micro-LED mLED is disposed, but the micro LED mLED may be disposed without removing the first insulating layer 114.

The first insulating layer 114 may include an organic layer, such as photo acrylic, or may be formed as a laminated structure of inorganic/organic layers or a laminated structure of inorganic/organic/inorganic layers.

A second insulating layer 116 is formed over the first insulating layer 114 on which the micro-LED mLED is mounted.

The second insulating layer 116 may include an organic layer, such as photo acrylic, or may include a laminated structure of inorganic/organic layers or a laminated structure of inorganic/organic/inorganic layers. The second insulating layer 116 covers the top area of the micro-LED mLED.

A first contact hole 114a and a second contact hole 114b are formed in the first insulating layer 114 and the second insulating layer 116 over the thin-film transistor TFT and the second electrode 109, respectively, so that the drain electrode 107 of the thin-film transistor TFT and the second electrode 109 are exposed to the outside. In addition, a third contact hole 116a and a fourth contact hole 116b are formed in the second insulating layer 116 over a first microelectrode 141 and a second microelectrode 143 of the micro-LED mLED, respectively, so that the first microelectrode 141 and the second microelectrode 143 are exposed to the outside.

A first connecting electrode 117a and a second connecting electrode 117b each including a transparent metal oxide, such as indium-tin oxide (ITO), indium-gallium-zinc oxide (IGZO), or indium-gallium oxide (IGO), are formed over the second insulating layer 116.

The first connecting electrode 117a is electrically connected to the drain electrode 107 of the thin-film transistor TFT and the first microelectrode 141 through the first contact hole 114a and the third contact hole 116a. The second connecting electrode 117b is electrically connected to the second electrode 109 and the second microelectrode 143 through the second contact hole 114b and the fourth contact hole 116b.

A control module 170 is disposed on the bottom surface of the first substrate 111a in the display area DA. The control module 170 may be the control printed circuit board CPCB on which the timing controller 140, a memory such as an EEPROM, the power management circuit 150 for driving the micro-LED mLED, and various signal lines are formed, or a printed circuit board on which the gate driving circuit 120 or the data driving circuit 130 for applying the gate signal or the data signal to the gate lines and the data lines is provided.

In addition, a signal line 151 is formed over the bottom surface of the first substrate 111a to electrically connect the second pad 153 and the control module 170.

A first through-hole 113a is formed in the first substrate 111a to extend therethrough from the top surface to the bottom surface, and a second through-hole 113b is formed in the second substrate 111b to extend therethrough from the top surface to the bottom surface. The first through-hole 113a and the second through-hole 113b may be formed at the same position or at a predetermined distance from each other.

The first through-hole 113a may be formed in an area in which the first pad 152 is disposed, and the second through-hole 113b may be formed in an area in which the second pad 153 is disposed.

Link lines 154 may be formed inside the first through-hole 113a and the second through-hole 113b, respectively. The link lines 154 electrically connect the first pad 152 and the second pad 153, such that a signal output from the control module 170 is delivered to the first pad 152 on the top surface of the second substrate 111b through the second pad 153 and the link lines 154, and then the thin-film transistor TFT is turned on through the gate line and the data line.

When the thin-film transistor TFT is turned on, a signal is supplied to the micro-LED mLED through the thin-film transistor TFT and the second electrode 109, so that the micro LED mLED emits light.

A connecting pattern 154a may be formed between the first substrate 111a and the second substrate 111b to connect the link lines 154 formed in the first through-hole 113a and the second through-hole 113b. When the first through-hole 113a and the second through-hole 113b are formed at the same position, the connection pattern 154a simply connects the link lines 154 formed in the first through-hole 113a and the second through-hole 113b. When the first through-hole 113a and the second through-hole 113b are formed at different positions, the connection pattern 154a may be formed in the shape of a signal line having a predetermined length between the first substrate 111a and the second substrate 111b to connect the link lines 154 formed in the first through-hole 113a and the second through-hole 113b.

A plurality of first through-holes 113a and a plurality of second through-holes 113b may be formed to be connected one-to-one to a plurality of gate pads and a plurality of data pads disposed on the top surface of the second substrate 111b.

The link lines 154 may be formed by stacking a metal, such as chromium (Cr), molybdenum (Mo), tantalum (Ta), copper (Cu), titanium (Ti), aluminum (Al), or an alloy thereof by sputtering, followed by etching. In another example, the link lines 154 may be formed by introducing a viscous liquid metal into the first through-hole 113a and the second through-hole 113b.

The link lines 154 may fill the entirety of the first through-hole 113a and the second through-hole 113b, or may be formed at a predetermined thickness on the circumferential inner surface of the first through-hole 113a and the second through-hole 113b. When the link lines 154 are formed only on the circumferential inner surface of the first through-hole 113a and the second through-hole 113b, the interiors of the first through-hole 113a and the second through-hole 113b may be filled with an insulating material, such as an inorganic material or an organic material.

In addition, a buffer layer 118 including an inorganic or organic material may be formed over the top surface of the second substrate 111b to cover the micro-LED mLED and the first pad 152 on the top surface of the second substrate 111b.

In the display device 100 of the present disclosure, the heat dissipation sheet 119 having the path pattern allowing liquid metal to flow therethrough may be disposed between the first substrate 111a and the second substrate 111b so as to improve the heat dissipation performance of the display panel 110 and bring about low power and greenhouse gas reduction effects.

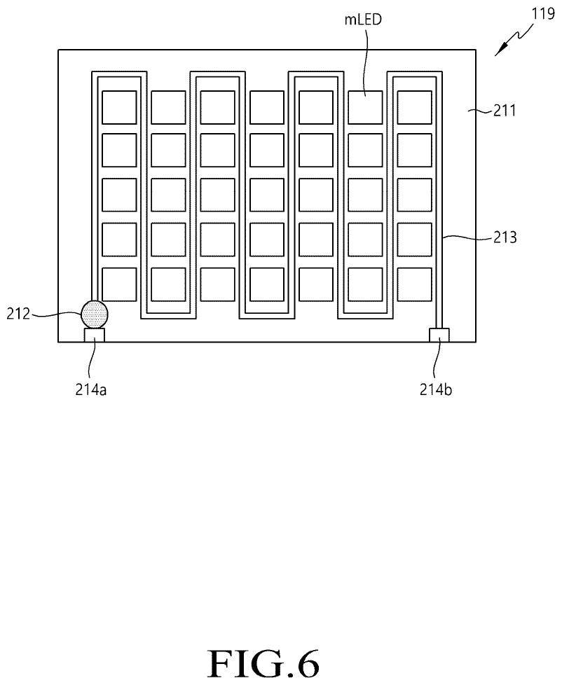

FIG. 6 is a plan view conceptually illustrating the structure of the heat dissipation sheet disposed between the first substrate and the second substrate in the display device according to embodiments of the present disclosure.

Referring to FIG. 6, the display device 100 according to embodiments may include the heat dissipation sheet 119 between the first substrate 111a and the second substrate 111b to cool the heat dissipated (or radiated) from the micro-LEDs mLED.

The heat dissipation sheet 119 may include a sheet body 211, a liquid metal inlet 212 provided on a first side of the sheet body 211 such that liquid metal is injected therethrough, a path pattern 213 allowing liquid metal to flow therethrough along a surface of the sheet body 211, a first flow voltage pad 214a applying a voltage to the liquid metal inlet 212, and a second flow voltage pad 214b connected to an end of the path pattern 213.

The heat dissipation sheet 119 may be disposed between the first substrate 111a and the second substrate 111b of the display panel 110. The sheet body 211 may be formed of polyimide, or may be formed of an adhesive material capable of bonding the first substrate 111a and the second substrate 111b.

The sheet body 211 may be formed of a transparent material to minimize luminance reduction of the micro-LEDs mLED.

The liquid metal inlet 212 is a portion through which the liquid metal is injected to transfer heat generated in a high temperature area of the display panel 110 to a low temperature area. The liquid metal inlet 212 may be provided in an area of the display panel 110 in which high temperature heat is generated. For example, the liquid metal inlet 212 may be provided at a position adjacent to the driving circuit.

In another example, in a case where the display device 100 is provided with a cooling system, the liquid metal inlet 212 may be provided at a position adjacent to the cooling system.

The liquid metal may be formed of a gallium metal, a gallium-indium eutectic alloy, or Galinstan.

The gallium-indium eutectic alloy is an alloy of gallium and indium having a constant mass ratio, the electrical resistivity of which is not significantly different from that of the metals. Such gallium-indium eutectic alloys exist in the liquid phase at or above 15.3° C. and therefore have great flexibility.

Galinstan is an alloy of gallium, indium, and tin which has a low melting point of −19° C. and is therefore a liquid at room temperature.

The path pattern 213 has a groove structure engraved in the upper surface of the sheet body 211 to allow the liquid metal to flow therethrough. The path pattern 213 may be formed in a variety of shapes, and may extend in a zigzag pattern along the spaces between the adjacent micro LEDs mLED which dissipate (or radiate) heat.

The path pattern 213 may be formed as a single pattern on the display panel 110, or it may be formed as a plurality of separate patterns.

A first flow voltage pad 214a which may apply a flow voltage for the flow of the liquid metal is provided at a position adjacent to the liquid metal inlet 212. In addition, a second flow voltage pad 214b is provided on a second side of the path pattern 213.

For example, when a (+) voltage is applied to the first flow voltage pad 214a and a (−) voltage is applied to the second flow voltage pad 214b, the liquid metal will migrate from the liquid metal inlet 212 to the second flow voltage pad 214b.

Accordingly, the liquid metal that has absorbed the heat generated in the vicinity of the hot liquid metal inlet 212 may flow along the path pattern 213 toward the second flow voltage pad 214b having a lower temperature, thereby lowering the temperature of the heat in the hot area.

When the liquid metal flows to the second flow voltage pad 214b and the temperature decreases, the liquid metal may be controlled to flow back to the liquid metal 212 by changing the potential of the second flow voltage pad 214b to a (+) voltage and changing the potential of the first flow voltage pad 214a to a (−) voltage.

In this manner, the heat generated in the high temperature area of the display panel 110 may be absorbed by the liquid metal to move along the path pattern 213 to the low temperature area, thereby achieving the effect of dissipating heat generated in the high temperature area of the display panel 110 to the low temperature area.

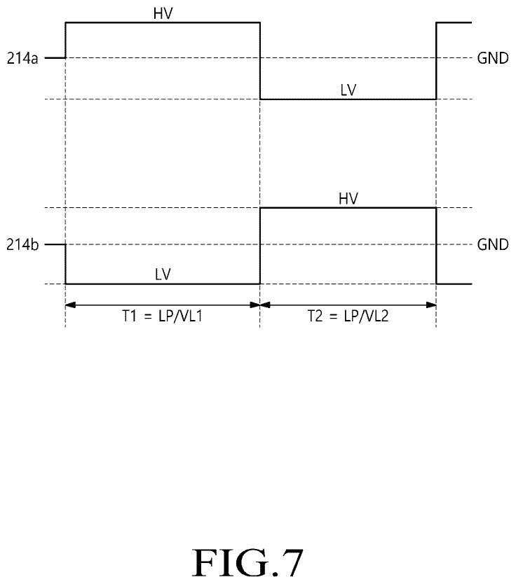

FIG. 7 is a signal waveform diagram illustrating an example operation of the flow voltage pad in the display device according to embodiments of the present disclosure.

Referring to FIG. 7, the display device 100 according to embodiments may include the heat dissipation sheet 119 between the first substrate 111a and the second substrate 111b to cool heat dissipated from the micro-LEDs mLED.

In this case, the path pattern 213 allowing liquid metal to flow therethrough is provided in the heat dissipation sheet 119. The first flow voltage pad 214a, through which a flow voltage is applicable for the flow of the liquid metal, may be provided at a position adjacent to the liquid metal inlet 212 of the path pattern 213, and the second flow voltage pad 214b may be provided at an end of the path pattern 213.

In this state, during a first period T1, a high voltage HV having a (+) level is applied to the first flow voltage pad 214a and a low voltage LV having a (−) level is applied to the second flow voltage pad 214b. Accordingly, during the first period T1, the liquid metal flows from the liquid metal inlet 212 to the second flow voltage pad 214b located at the end of the path pattern 213.

In this case, the first period T1 may be determined by the first velocity VL1 of the liquid metal flowing along the length LP from the liquid metal inlet 212 to the end of the path pattern 213. That is, the first period T1 may be determined as the length LP of the path pattern divided by the first velocity VL1 of the liquid metal.

During the first period T1, as the liquid metal reaches the end of the path pattern 213, the liquid metal dissipates internal heat.

After the first period T1, during the second period T2, a low voltage LV having a (−) level is applied to the first flow voltage pad 214a and a high voltage HV having a (+) level is applied to the second flow voltage pad 214b. Accordingly, during the second period T2, the liquid metal flows from the second flow voltage pad 214b located at the end of the path pattern 213 to the liquid metal inlet 212.

In this case, the second period T2 may be determined by the second velocity VL2 of the liquid metal flowing along the length LP of the path pattern 213. That is, the second period T2 may be determined as the length LP of the path pattern divided by the second velocity VL2 of the liquid metal.

In this manner, the liquid metal absorbs heat from the high temperature area and dissipates the heat while flowing to the low temperature area during the first period T1, and then moves back to the high temperature area to absorb heat during the second period T2, thereby achieving the effect of dissipating heat absorbed from the high temperature area to the low temperature area.

In addition, it is shown here that a single first flow voltage pad 214a and a single second flow voltage pad 214b are provided at opposite ends of the path pattern 213, respectively, but a plurality of flow voltage pads may also be provided at intermediate positions of the path pattern 213 to precisely control the path and velocity of the flow of the liquid metal.

The present disclosure is not limited to a display device including the micro-LEDs mLED or a display device having a tiled structure, but is applicable to any display device having a structure in which the heat dissipation sheet 119 having a path pattern allowing liquid metal to flow therethrough between the first substrate 111a and the second substrate 111b may be disposed.

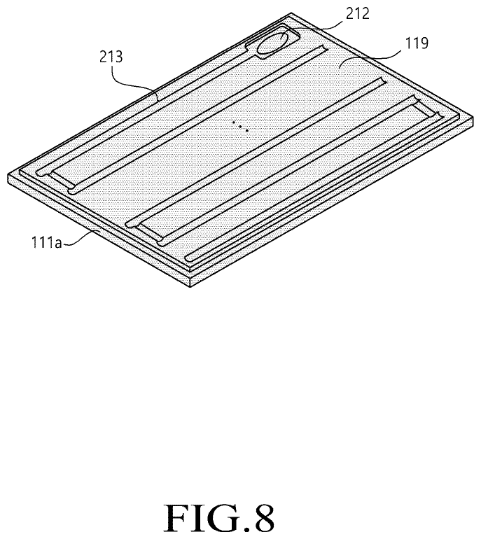

FIGS. 8 to 11 are perspective views illustrating an example process of fabricating a display panel according to embodiments of the present disclosure.

First, in a display panel 110 according to embodiments, a heat dissipation sheet 119 is formed on a first substrate 111a, as shown in FIG. 8.

The heat dissipation sheet 119 has a liquid metal inlet 212 through which the liquid metal is injected and a path pattern 213 through which the liquid metal may flow.

The liquid metal inlet 212 may be disposed adjacent to a position in the display panel 110 in which high temperature heat is generated. In addition, when the display panel 110 is disposed in a cooling system, the liquid metal inlet 212 may be located adjacent to the cooling system. The sheet body of the heat dissipation sheet 119 may be formed of polyimide.

In this case, an adhesive may be provided on the periphery of at least a portion of the heat dissipation sheet 119, such that the heat dissipation sheet 119 may be formed smaller than the first substrate 111a.

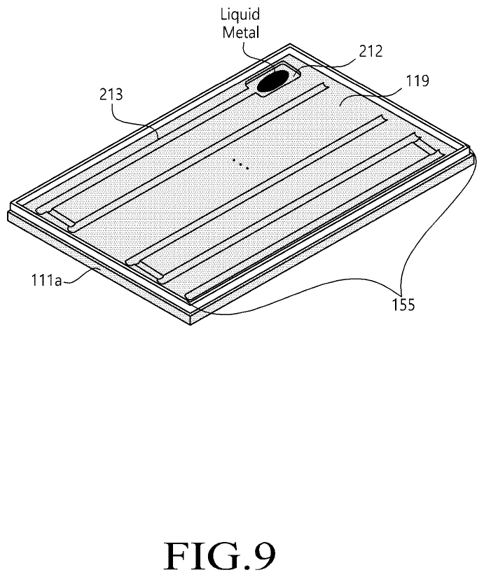

Next, as shown in FIG. 9, a sealant 155 is disposed on a portion of the periphery of the heat dissipation sheet 119, and liquid metal is injected into the liquid metal inlet 212.

The sealant 155 may serve to seal the peripheral portions of the heat dissipation sheet 119 while bonding the lower first substrate 111a to the upper second substrate 111b. Therefore, the sealant 155 may be formed of an adhesive material.

The liquid metal injected into the liquid metal inlet 212 may be formed of gallium metal, gallium-indium eutectic alloy, Galinstan, or the like.

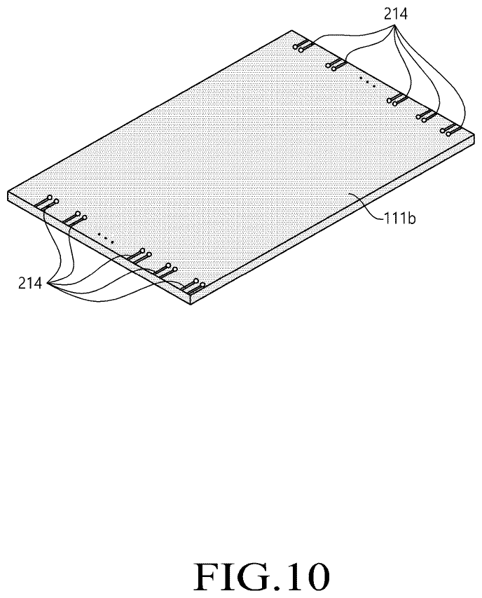

As shown in FIG. 10, a plurality of flow voltage pads 214 may be provided on the second substrate 111b to control the flow of the liquid metal. The flow voltage pads 214 may be disposed at a position corresponding to the liquid metal inlet 212 and at a position corresponding to the end of the path pattern 213.

In addition, the flow voltage pads 214 may be further disposed at major bend points at which the direction of the path pattern 213 changes so as to effectively control the direction and speed of the flow of the liquid metal.

Either a (+) flow voltage or a (−) flow voltage may be applied, depending on the direction of the flow of the liquid metal. Thus, the flow voltage pads 214 may control a voltage level applied to the flow voltage pads 214, or the flow voltage pads 214 may be arranged to be divided into high-potential flow voltage pads to which the (+) flow voltage is applied and low-potential flow voltage pads to which the (−) flow voltage is applied.

The flow voltage pads 214 are shown here as being provided on the second substrate 111b, but the flow voltage pads 214 may also be provided on the first substrate 111a.

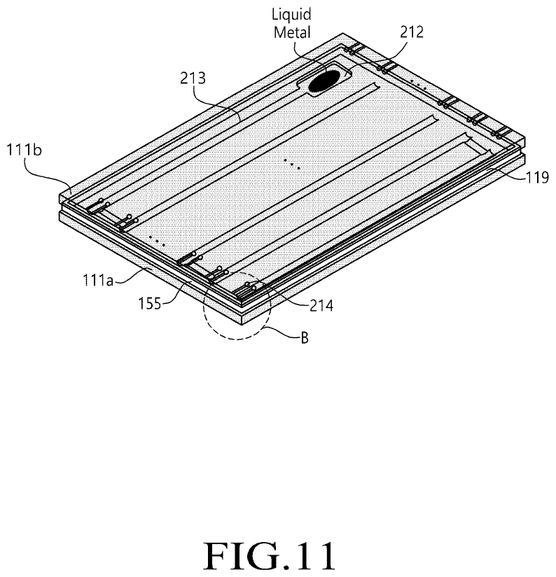

When the fabrication of the second substrate 111b is completed, the first substrate 111a and the second substrate 111b are bonded to each other to cover the heat dissipation sheet 119, as shown in FIG. 11. The first substrate 111a and the second substrate 111b may be bonded by a sealant 155 provided on peripheral portions of the heat dissipation sheet 119.

In this case, an adhesive layer such as an optical clear adhesive (OCA) may further be disposed between the heating dissipation sheet 119 having the liquid metal path pattern 213 and the second substrate 111b to prevent the liquid metal from leaking.

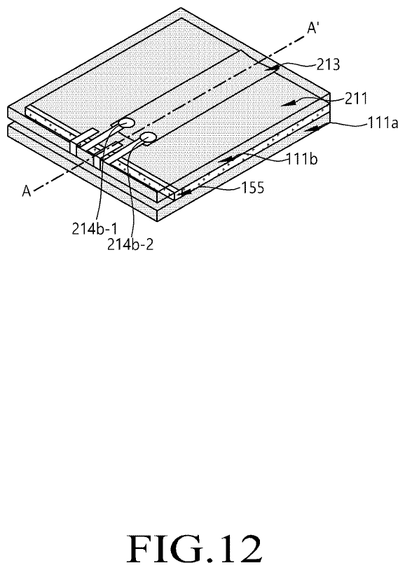

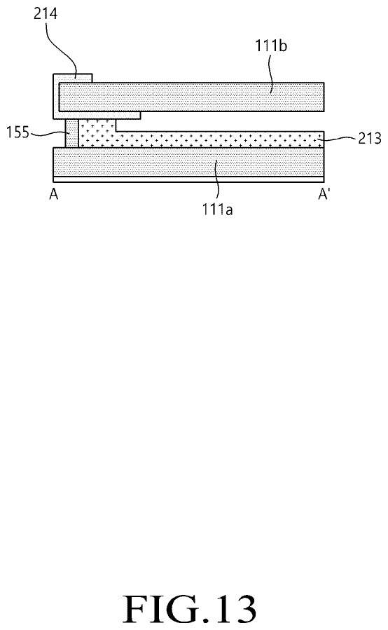

FIG. 12 is an enlarged perspective view of part B of FIG. 11 according to one embodiment of the present disclosure, and FIG. 13 is a cross-sectional view taken along line A-A′ of FIG. 12 according to one embodiment of the present disclosure.

Referring to FIGS. 12 and 13, the display device 100 of the present disclosure may include the heat dissipation sheet 119 which has the path pattern 213 allowing liquid metal to flow therethrough and is disposed between the first substrate 111a and the second substrate 111b of the display panel 110.

The path pattern 213 includes engraved grooves formed in the sheet body 211, in which the engraved grooves may extend in a zigzag pattern between the micro-LEDs mLED located thereover.

The flow voltage pads 214 may be provided at the ends or bends of the path pattern 213, in where a flow voltage is applied to the flow voltage pads 214 to control the flow of the liquid metal. The flow voltage pads 214 may be provided on the first substrate 111a, or may be provided on the second substrate 111b.

The flow voltage pads located at the ends of the path pattern 213 may be configured such that a (+) voltage and a (−) voltage may be selectively applied to a single pad, or may include a high-potential flow voltage pad 214b-1 to which a high-potential flow voltage having a (+) level is applied and a low-potential flow voltage pad 214b-2 to which a low-potential flow voltage having a (−) level is applied.

In addition, the flow voltage pads 214b-1 and 214b-2 located at the ends of the path pattern 213 may be arranged to surround the side surfaces of the second substrate 111b, and may overlap the sealant 155 located thereunder and a portion of the path pattern 213.

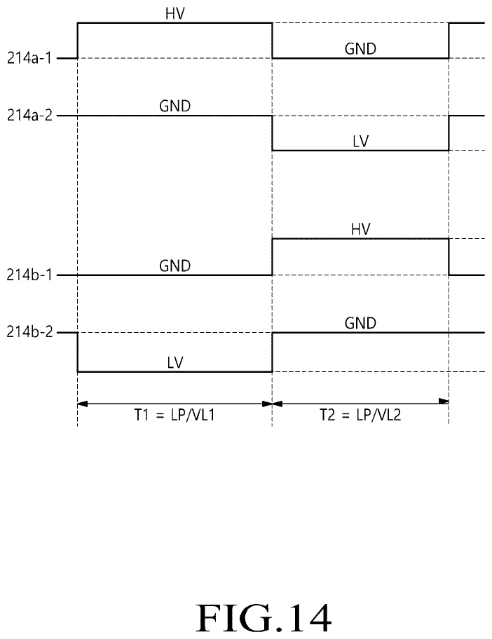

FIG. 14 is a signal waveform diagram illustrating another example operation of the flow voltage pad in the display device according to embodiments.

Referring to FIG. 14, the display device 100 according to embodiments may include the heat dissipation sheet 119 provided between the first substrate 111a and the second substrate 111b to cool heat dissipated from the micro-LEDs mLED.

In this case, a path pattern 213 allowing liquid metal to flow therethrough is provided in the heat dissipation sheet 119. A first high-potential flow voltage pad 214a-1 and a first low-potential flow voltage pad 214a-2 capable of applying a flow voltage for the flow of the liquid metal may be provided at positions adjacent to the liquid metal inlet 212 of the path pattern 213, and a second high-potential flow voltage pad 214b-1 and a second low-potential flow voltage pad 214b-2 may be provided at an end of the path pattern 213.

Here, the high-potential flow voltage pads 214a-1 and 214b-1 are the pads to which a high voltage HV having a (+) level is applied, and the low-potential flow voltage pads 214a-2 and 214a-2 are the pads to which a low voltage LV having a (−) level is applied.

In this state, in a first period T1, the high voltage HV having a (+) level is applied to the first high-potential flow voltage pad 214a-1, while the first low-potential flow voltage pad 214a-2 remains at ground level. Further, the low voltage LV having a (−) level is applied to the second low-potential flow voltage pad 214b-2, while the second high-potential flow voltage pad 214b-1 remains at ground level. Accordingly, during the first period T1, the liquid metal flows from the liquid metal inlet 212 to the second flow voltage pads 214b-1 and 214b-2 located at the end of the path pattern 213.

In this case, the first period T1 may be determined by the first velocity VL1 of the liquid metal flowing along the length LP from the liquid metal inlet 212 to the end of the path pattern 213. That is, the first period T1 may be determined as the length LP of the path pattern divided by the first velocity VL1 of the liquid metal.

During the first period T1, as the liquid metal reaches the end of the path pattern 213, the liquid metal dissipates internal heat.

After the first period T1, during the second period T2, a low voltage LV having a (−) level is applied to the first low-potential flow voltage pad 214a-2, and the first high-potential flow voltage pad 214a-1 remains at ground level. In addition, a high voltage HV having a (+) level is applied to the second high-potential flow voltage pad 214b-1, and the second low-potential flow voltage pad 214b-2 remains at ground level. Accordingly, during the second period T2, the liquid metal flows from the second flow voltage pads 214b-1 and 214b-2 located at the end of the path pattern 213 to the liquid metal inlet 212.

In this case, the second period T2 may be determined by the second velocity VL2 of the liquid metal flowing along the length LP of the path pattern 213. That is, the second period T2 may be determined as the length LP of the path pattern divided by the second velocity VL2 of the liquid metal.

In this manner, the liquid metal dissipates the heat absorbed from the high temperature area while flowing to the low temperature area during the first period T1, and then moves back to the high temperature area to absorb heat during the second period T2, thereby achieving the effect of dissipating heat absorbed from the high temperature area to the low temperature area.

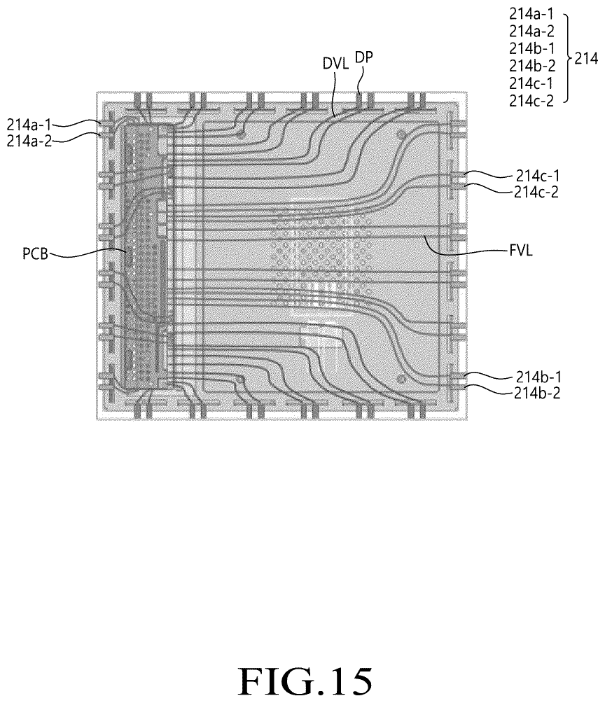

FIG. 15 illustrates an example of a signal line connecting configuration on the display backside in the display device according to embodiments of the present disclosure.

Referring to FIG. 15, the display device 100 according to embodiments may have driving voltage lines DVL transferring a driving voltage to driving voltage pads DP and flow voltage lines FVL transferring a flow voltage to flow voltage pads 214, wherein the driving voltage lines DVL and flow voltage lines FVL are disposed on the backside of the first substrate 111a.

That is, the driving voltage lines DVL extending through a printed circuit board (PCB) coupled to the first substrate 111a may be connected to the driving voltage pads DP located on a first side of the display panel 110 along the backside of the first substrate 111a, and the flow voltage lines FVL may be connected to the flow voltage pads 214 located on a second side of the display panel 110 along the backside of the first substrate 111a.

A first high-potential flow voltage pad 214a-1 and a first low-potential flow voltage pad 214a-2 capable of applying a flow voltage for the flow of the liquid metal may be provided at positions adjacent to the liquid metal inlet 212, and a second high-potential flow voltage pad 214b-1 and a second low-potential flow voltage pad 214b-2 may be provided at the end of the path pattern 213. In addition, a third high-potential flow voltage pad 214c-1 and a third low-potential flow voltage pad 214c-2 may be further provided at major bend points at which the direction of the path pattern 213 changes.

In this case, the flow of the liquid metal may be more effectively controlled by controlling the voltages of the third high-potential flow voltage pad 214c-1 and the third low-potential flow voltage pad 214c-2 according to the position of the flowing liquid metal.

Here, the high-potential flow voltage pads 214a-1, 214b-1, and 214c-1 are the pads to which high voltages HV having a (+) level are applied, and the low-potential flow voltage pads 214a-2, 214a-2, and 214c-2 are the pads to which low voltages LV having a (−) level are applied.

The printed circuit board may be a source printed circuit board on which the data driving circuit is mounted, or may be a control printed circuit board on which a timing controller is mounted.

The printed circuit board may be disposed adjacent to a short side of the display panel 110. In this case, the first side on which the driving voltage pads DP are provided may be a long side of the display panel 110, and the second side on which the flow voltage pads 214 are provided may be the short side of the display panel 110.

Accordingly, the flow voltage pads 214 are provided on the short side of the display panel 110 adjacent to the printed circuit board on which the driving circuit is mounted, and the path pattern 213 provided in the heat dissipation sheet 119 may be referred to as a structure extending along the long side of the display panel 110.

As described above, the formation of the flowing voltage pads 214 in the area adjacent to the printed circuit board may move the heat generated by the printed circuit board along the path pattern 213 of the heat dissipation sheet 119 to the low temperature area (e.g., away from the printed circuit board), thereby achieving the heat dissipation performance.

In the display device 100 of the present disclosure, the path patterns 213 included in the heat dissipation sheet 119 may be configured such that different path patterns are provided in an area in which high temperature heat is generated and an area in which low temperature heat is generated.

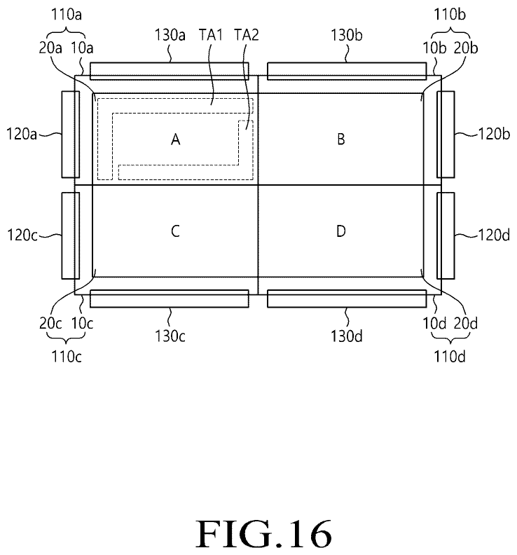

FIG. 16 schematically illustrates a tiled display device in which a plurality of display panels are disposed adjacent to each other according to one embodiment of the present disclosure.

Referring to FIG. 16, the tiled display device is provided by tiling a plurality of display panels 110a, 110b, 110c, and 110d in areas A, B, C, and D, respectively, such that the display panels 110a, 110b, 110c, and 110d contact each other.

In this case, the display panels 110a, 110b, 110c, and 110d are provided with gate driving circuits 120a, 120b, 120c, and 120d and data driving circuits 130a, 130b, 130c, and 130d on the peripheral portions thereof, each of which is controlled by a timing controller (not shown).

For example, the first display panel 110a provided in the area A may include a first lower substrate 10a and a first upper substrate 20a. On the first lower substrate 10a, an array of thin-film transistors is provided in a display area, and the first gate driving circuit 120a and the first data driving circuit 130a are provided in a non-display area. On the first upper substrate 20a, a light-emitting element such as a micro-LED is provided. In addition, a heat dissipation sheet having a path pattern allowing liquid metal to flow therethrough may be disposed between the first lower substrate 10a and the first upper substrate 20a.

The second display panel 110b provided in the area B may include a second lower substrate 10b and a second upper substrate 20b. On the second lower substrate 10b, an array of thin-film transistors is provided in a display area, and the second gate driving circuit 120b and the second data driving circuit 130b are provided in a non-display area. On the second upper substrate 20b, a light-emitting element such as a micro-LED is provided. In addition, a heat dissipation sheet having a path pattern allowing liquid metal to flow therethrough may be disposed between the second lower substrate 10b and the second upper substrate 20b.

The third display panel 110c provided in the area C may include a third lower substrate 10c and a third upper substrate 20c. On the third lower substrate 10c, an array of thin-film transistors is provided in a display area, and the third gate driving circuit 120c and the third data driving circuit 130c are provided in a non-display area. On the third upper substrate 20c, a light-emitting element such as a micro-LED is provided. In addition, a heat dissipation sheet having a path pattern allowing liquid metal to flow therethrough may be disposed between the third lower substrate 10c and the third upper substrate 20c.

The fourth display panel 110d provided in the area D may include a fourth lower substrate 10d and a fourth upper substrate 20d. On the fourth lower substrate 10d, an array of thin-film transistors is provided in a display area, and the fourth gate driving circuit 120d and the fourth data driving circuit 130d are provided in a non-display area. On the fourth upper substrate 20d, a light-emitting element such as a micro-LED is provided. In addition, a heat dissipation sheet having a path pattern allowing liquid metal to flow therethrough may be disposed between the fourth lower substrate 10d and the fourth upper substrate 20d.

In the tiled display device, the display panel 110a, 110b, 110c, and 110d are disposed adjacent to each other in a portion where none of the gate driving circuits 120a, 120b, 120c, and 120d or the data driving circuit 130a, 130b, 130c, and 130d is provided.

In such a tiled display device, the area adjacent to the drive circuitry may be a hot area TA1 in which high temperature heat is generated, and the area in which the display panels are adjacent to each other may be a cold area TA2 in which low temperature heat is generated.

The display device of the present disclosure may achieve effective heat dissipation performance by varying the density of the path pattern allowing liquid metal to flow therethrough in the high temperature area and the low temperature area of the display panel, respectively.

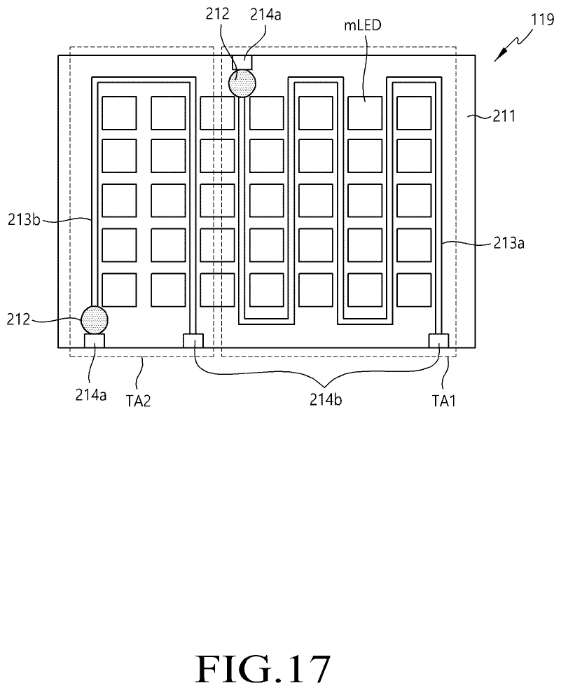

FIG. 17 illustrates a case in which the display panel of the display device according to embodiments has different path patterns in a high temperature area and a low temperature area as an example.

Referring to FIG. 17, the display device 100 according to embodiments may include a heat dissipation sheet 119 between the first substrate 111a and the second substrate 111b to cool heat dissipated from the micro-LEDs mLED.

The heat dissipation sheet 119 may include a sheet body 211, liquid metal inlets 212 provided on sides of the sheet body 211 and allowing liquid metal to injected therethrough, path patterns 213 allowing liquid metal to flow therethrough along the surface of the sheet body 211, first flow voltage pads 214a applying a voltage to the liquid metal inlets 212, and second flow voltage pads 214b connected to ends of the path patterns 213.

Each of the liquid metal inlets 212 is a portion through which the liquid metal is injected to absorb heat generated from the display panel 110. In this case, the liquid metal inlets 212 may be provided in a high temperature area TA1 and a low temperature area TA2, respectively.

The liquid metal absorbing the heat generated in the high temperature area TA1 may flow along a long path pattern 213a to increase heat dissipation. To this end, the path pattern 213a provided in the high temperature area TA1 may be densely arranged such that the path pattern 213b provided in the low temperature area TA2 has a shorter path than the path pattern 213a provided in the high temperature area TA1. For example, the path pattern 213a provided in the high temperature area TA1 may be arranged to extend through the space between the micro-LEDs mLED in each row, while the path pattern 213b provided in the low temperature area TA2 may be arranged to extend through the space between two rows of micro LEDs mLED.

In addition, the first flow voltage pads 214a capable of applying a flow voltage to control flow of liquid metal are provided at positions adjacent to the liquid metal inlets 212, and a second flow voltage pad 214b is provided on second sides of the path patterns 213a and 213b.

For example, when a (+) voltage is applied to the first flow voltage pads 214a and a (−) voltage is applied to the second flow voltage pads 214b, the liquid metal flows from the liquid metal inlets 212 to the second flow voltage pads 214b.

Accordingly, the liquid metal that has absorbed heat generated in the vicinity of the hot liquid metal inlets 212 may dissipate heat by flowing to the second flow voltage pads 214b along the path patterns 213a and 213b.

When the liquid metal flows to the second flow voltage pads 214b to lower the temperature, the liquid metal may be caused to flow back to the liquid metal inlet 212 by changing the potential of the second flow voltage pads 214b to a (+) voltage and the potential of the first flow voltage pads 214a to a (−) voltage.

The embodiments described above are briefly reviewed as follows.

The display device according to the present disclosure may include: a display panel including a plurality of light-emitting elements; a driving circuit configured to drive the display panel. The display panel may include: a first substrate with the driving circuit being provided on a first surface thereof; a second substrate with the light-emitting elements being disposed on a top portion thereof; and a heat dissipation sheet disposed between the first substrate and the second substrate, and including a path pattern allowing liquid metal to flow therethrough.

Each of the light-emitting elements may be a micro light-emitting diode.

The path pattern may extend in a zigzag pattern along spaces between the light-emitting elements.

The heat dissipation sheet may include a liquid metal inlet through which the liquid metal is injected.

The liquid metal inlet may be located in a high temperature area of the display panel.

The liquid metal may include gallium, a gallium-indium eutectic alloy, or Galinstan.

The second substrate may include: a first flow voltage pad applying a first flow voltage to the liquid metal inlet; and a second flow voltage pad applying a second flow voltage to an end of the path pattern.

In the display device, a high voltage having a (+) level may be applied to the first flow voltage pad and a low voltage having a (−) level is applied to the second flow voltage pad during a first period, and a low voltage having a (−) level may be applied to the first flow voltage pad and a high voltage having a (+) level is applied to the second flow voltage pad during a second period.

The second substrate may include: a first high-potential flow voltage pad applying a high voltage having a (+) level to the liquid metal inlet; a first low-potential flow voltage pad applying a low voltage having a (−) level to the liquid metal inlet; a second high-potential flow voltage pad applying a high voltage having a (+) level to an end of the path pattern; and a second low-potential flow voltage pad applying a low voltage having a (−) level to the end of the path pattern.

A high voltage having a (+) level may be applied to the first high-potential flow voltage pad and a low voltage having a (−) level is applied to the second low-potential flow voltage pad during a first period, and a low voltage having a (−) level may be applied to the first low-potential flow voltage pad and a high voltage having a (+) level is applied to the second high-potential flow voltage pad during a second period.

The second substrate may further include a third flow voltage pad disposed at a bend point at which a direction of the path pattern changes.

The display panel may further include a sealant provided on a peripheral portion of the heat dissipation sheet to bond the first substrate and the second substrate.

The path pattern may include: a first path pattern provided in a high temperature area of the display panel; and a second path pattern provided in a low temperature area of the display panel and separated from the first path pattern.

The high temperature area may be adjacent to the driving circuit.

The first path pattern may have a higher density than the second path pattern.

The display device may further include an adhesive layer disposed between the heat dissipation sheet and the second substrate.

In addition, the display panel according to the present disclosure may include: a first substrate with a driving circuit being provided on a first surface thereof; a second substrate with light-emitting elements being disposed on a top portion thereof; and a heat dissipation sheet disposed between the first substrate and the second substrate, and including a path pattern allowing liquid metal to flow therethrough.

In addition, the display device according to the present disclosure may include: a plurality of display panels disposed adjacent to each other; and a plurality of driving circuits configured to drive the display panels, respectively. Each of the display panels may include: a first substrate with the driving circuit being provided on a first surface thereof; a second substrate with light-emitting elements being disposed on a top portion thereof; and a heat dissipation sheet disposed between the first substrate and the second substrate, and including a path pattern allowing liquid metal to flow therethrough.

The path pattern may include: a first path pattern provided in a high temperature area; and a second path pattern provided in a low temperature area and separated from the first path pattern.

The high temperature area may be adjacent to the driving circuits, and the low temperature area is adjacent to the display panels.

The first path pattern may have a higher density than the second path pattern.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A display device comprising:
a display panel including a plurality of light-emitting elements;
a driving circuit configured to drive the display panel,
wherein the display panel comprises:
a first substrate with the driving circuit being provided on a first surface of the first substrate;
a second substrate with the plurality of light-emitting elements on a top portion of the second substrate; and
a heat dissipation sheet between the first substrate and the second substrate, the heat dissipation sheet comprising a path pattern that allows liquid metal to flow therethrough.

2. The display device of claim 1, wherein each of the plurality of light-emitting elements comprises a micro light-emitting diode.

3. The display device of claim 1, wherein the path pattern extends in a zigzag pattern along spaces between the plurality of light-emitting elements.

4. The display device of claim 1, wherein the heat dissipation sheet comprises a liquid metal inlet through which the liquid metal is injected.

5. The display device of claim 4, wherein the liquid metal inlet is disposed on an area adjacent to the driving circuit.

6. The display device of claim 1, wherein the liquid metal comprises gallium, a gallium-indium eutectic alloy, or Galinstan.

7. The display device of claim 4, wherein the second substrate comprises:
a first flow voltage pad configured to apply a first flow voltage to the liquid metal inlet; and
a second flow voltage pad configured to apply a second flow voltage to an end of the path pattern.

8. The display device of claim 7, wherein a high voltage having a positive level is applied to the first flow voltage pad and a low voltage having a negative level is applied to the second flow voltage pad during a first period, and
a low voltage having the negative level is applied to the first flow voltage pad and a high voltage having positive level is applied to the second flow voltage pad during a second period.

9. The display device of claim 8, wherein the first period is determined by a first velocity of the liquid metal flowing along the length from the liquid metal inlet to the end of the path pattern, and
wherein the second period is determined by a second velocity of the liquid metal flowing along the length of the path pattern.

10. The display device of claim 4, wherein the second substrate comprises:
a first high-potential flow voltage pad configured to apply a high voltage having a positive level to the liquid metal inlet;
a first low-potential flow voltage pad configured to apply a low voltage having a negative level to the liquid metal inlet;
a second high-potential flow voltage pad configured to apply a high voltage having the positive level to an end of the path pattern; and
a second low-potential flow voltage pad configured to apply a low voltage having the negative level to the end of the path pattern.

11. The display device of claim 10, wherein the high voltage having the positive level is applied to the first high-potential flow voltage pad and the low voltage having the negative level is applied to the second low-potential flow voltage pad during a first period, and
the low voltage having the negative level is applied to the first low-potential flow voltage pad and the high voltage having the positive level is applied to the second high-potential flow voltage pad during a second period.

12. The display device of claim 11, wherein the first low-potential flow voltage pad and the second high-potential flow voltage pad remain at ground level during the first period, and
wherein the first high-potential flow voltage pad and the second low-potential flow voltage pad remain at ground level during the second period.

13. The display device of claim 11, wherein the first period is determined by a first velocity of the liquid metal flowing along the length from the liquid metal inlet to the end of the path pattern, and
wherein the second period is determined by a second velocity of the liquid metal flowing along the length of the path pattern.

14. The display device of claim 7, wherein the second substrate further comprises a third flow voltage pad at a bend point at which a direction of the path pattern changes.

15. The display device of claim 1, wherein the display panel further comprises a sealant on a peripheral portion of the heat dissipation sheet that bonds the first substrate and the second substrate.

16. The display device of claim 1, wherein the path pattern comprises:
a first path pattern in a high temperature area of the display panel; and
a second path pattern in a low temperature area of the display panel and separated from the first path pattern, the low temperature area having a temperature that is less than the high temperature area.

17. The display device of claim 16, wherein the high temperature area is adjacent to the driving circuit.

18. The display device of claim 16, wherein the first path pattern has a density that is higher than a density of the second path pattern.

19. The display device of claim 1, further comprising:
an adhesive layer between the heat dissipation sheet and the second substrate.

20. A display panel comprising:
a first substrate with a driving circuit on a first surface of the first substrate;
a second substrate with light-emitting elements on a top portion of the second substrate; and
a heat dissipation sheet between the first substrate and the second substrate, the heat dissipation sheet comprising a path pattern that allows liquid metal to flow therethrough.
